(19) United States
(12) Patent Application Publication
(10) Pub. No.: US 2024/0203804 A1
(43) Pub. Date: Jun. 20, 2024

(54) ENGINEERED SEMICONDUCTOR SUBSTRATE

(71) Applicant: Micron Technology, Inc., Boise, ID (US)

(72) Inventors: Darwin A. Clampitt, Wilder, ID (US); Roger W. Lindsay, Boise, ID (US); Lisa M. Clampitt, Boise, ID (US)

(21) Appl. No.: 18/514,563

(22) Filed: Nov. 20, 2023

Related U.S. Application Data
(60) Provisional application No. 63/432,571, filed on Dec. 14, 2022.

(51) Int. Cl. H01L 23/13; B28D 5/00; H01L 21/18; H01L 21/304; H01L 23/14

(52) U.S. Cl. CPC H01L 23/13; B28D 5/0005; H01L 21/187; H01L 21/304; H01L 23/147; H01L 25/0657

(57) ABSTRACT

A semiconductor device assembly is provided. The semiconductive device assembly includes a semiconductor die with a substrate having an engineered portion and a semiconductive portion. The engineered portion includes one or more of: a sintered material, a corrugated material, oriented strands of material compressed to form a solid structure, layers of material compressed to form a solid structure, or a material arranged to form one or more planar trusses. The semiconductive portion is adhered directly to the engineered portion. A layer of dielectric material is disposed at the semiconductive portion, and circuitry is disposed at the layer of dielectric material. In doing so, a cost-efficient and mechanically robust semiconductor device may be assembled.

### CROSS-REFERENCE TO RELATED APPLICATION(S)

The present application claims priority to U.S. Provisional Patent Application No. 63/432,571, filed Dec. 14, 2022, the disclosure of which is incorporated herein by reference in its entirety.

### TECHNICAL FIELD

The present disclosure generally relates to semiconductor device assemblies, and more particularly relates to an engineered semiconductor substrate.

### BACKGROUND

Microelectronic devices generally have a die (i.e., a chip) that includes integrated circuitry with a high-density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIG. 2 illustrates a simplified schematic cross-sectional view of a semiconductor device assembly in accordance with an embodiment of the present technology.

FIGS. 3-9 illustrate simplified schematic cross-sectional views of a series of steps for fabricating semiconductor device assemblies in accordance with an embodiment of the present technology.

FIG. 10 illustrates a simplified schematic cross-sectional view of a semiconductor device assembly in accordance with an embodiment of the present technology.

FIG. 11 illustrates a schematic view of a system that includes a semiconductor device assembly configured in accordance with an embodiment of the present technology.

FIG. 12 illustrates a method of making a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

One such technique is to implement multiple circuit components within a single package. For example, stacked semiconductor devices enable multiple semiconductor dies to be stacked on top of one another to increase the number of circuit elements within a package without increasing its footprint. To create devices that can accommodate the complex computations required by modern devices, designers continue to increase the number of dies within a stacked semiconductor device. Often, the thicknesses of substrates on which these die stacks are implemented are reduced to create space for the additional dies within the package, thus decreasing the mechanical and thermal strength of the semiconductor device. Concurrently, the additional dies may increase the thermal or mechanical stresses on these semiconductor devices, which in turn, may lead to die warpage or cracking and reduce yield. These structural failures can create bottlenecks in the manufacturing process and increase cost due to waste.

In addition to structural concerns, some substrates may be costly to manufacture due to the cost of raw materials and waste introduced in some substrate manufacturing processes. For example, some substrates may be entirely created from bulk crystalline silicon (e.g., or any other semiconductive material, such as germanium, silicon-germanium alloy, gallium arsenide, gallium nitride, etc.) that has been refined to remove impurities. In total, the substrate manufacturing process can include complex operations that are performed over multiple weeks, which can further complicate downstream manufacturing. As a result, crystalline silicon substrates may be costly to manufacture.

Some manufacturers may utilize silicon-on-insulator (SOI) or silicon-on-poly aluminum nitride (SOPAN) substrates, which attach a semiconductive layer to a non-semiconductive material to enable circuitry to be disposed at the semiconductive surface, without requiring the substrate to be entirely semiconductive. The semiconductive material may be implanted from a donor wafer until the donor wafer is insufficiently thick to support another implantation. At that point, the donor wafer may be discarded or repurposed for another application. In this way, these techniques may introduce additional waste into the manufacturing process, thereby increasing manufacturing cost. Moreover, these substrates often utilize sapphire, glass, or other insulators as the non-conductive material, which may be too costly or have insufficient strength to implement some semiconductor devices.

To address these drawbacks and others, various embodiments of the present application provide semiconductor device assemblies that implement an engineered semiconductor substrate. A semiconductive device assembly is provided that includes a semiconductor die with a substrate having an engineered portion and a semiconductive portion. The engineered portion includes one or more of: a sintered material, a corrugated material, oriented strands of material compressed to form a solid structure, layers of material compressed to form a solid structure, or a material arranged to form one or more planar trusses. The semiconductive portion is adhered directly to the engineered portion. A layer of dielectric material is disposed at the semiconductive portion, and circuitry is disposed at the layer of dielectric material. In doing so, a cost-efficient and mechanically robust semiconductor device may be assembled.

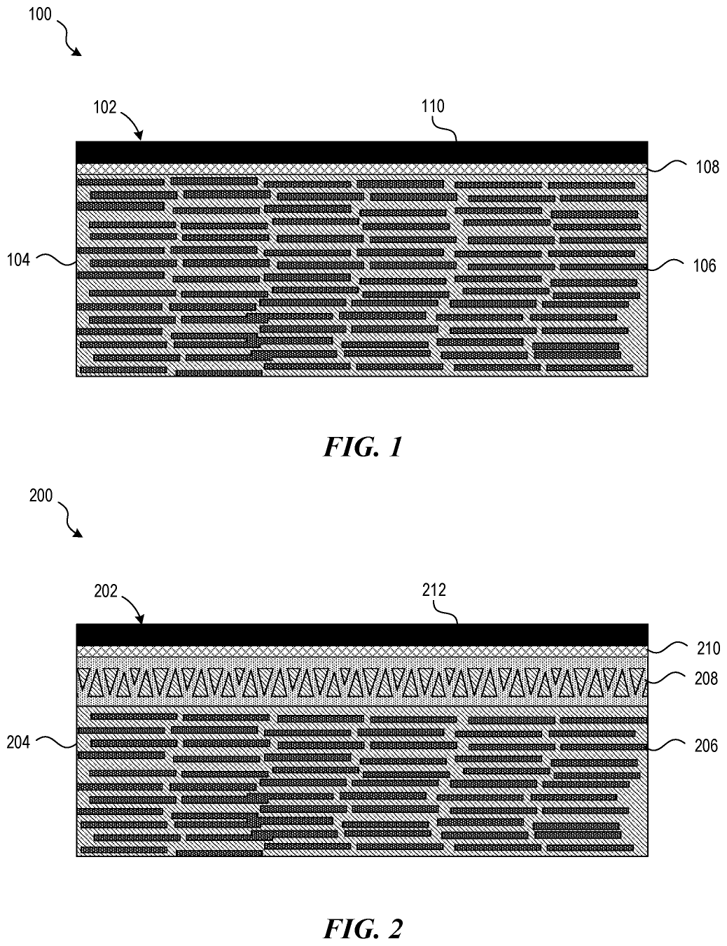

FIG. 1 is a simplified schematic cross-sectional view of a semiconductor device assembly 100 in accordance with embodiments of the present technology. The semiconductor device assembly 100 may correspond to a semiconductor die 102 or a collection of semiconductor dies implemented on a substrate 104. In contrast to some semiconductor substrates, the substrate 104 may include an engineered portion 106 (e.g., non-semiconductive, non-crystalline, or non-glass) and a semiconductive portion 108. The engineered portion 106 may include a material that is non-crystalline. The engineered portion 106 may be mechanically engineered using mechanical principles to form a structurally robust substrate. The engineered portion 106 may be formed from any number of bulk materials or laminates. For example, the engineered portion 106 may be formed from dusts, laminates, or oriented strands of material. In this way, the substrate 104 is not required to be cut from a larger structure, but instead, smaller pieces of material may be combined to form the engineered portion 106, which may, in turn, reduce the cost to manufacture the substrate 104. Moreover, the material used to manufacture the engineered portion 106 may be cheaper than bulk silicon or other substrate materials.

Various techniques may be used to mechanically engineer the engineered portion 106 of the substrate 104. As non-limiting examples, the engineered portion 106 may include a powder sintered to form a solid material, sheets of material compressed to form a solid structure, oriented strands of material compressed to form a solid structure (e.g., similar to the process used to manufacture oriented strand board), a corrugated material, or a material arranged to form one or more planar trusses. The engineered portion 106 may have one or more repeating structures (e.g., layers, trusses, corrugations, or the like). The engineered portion 106 may be formed from silicon dust, laminates (e.g., polytetrafluorethylene, pre-preg, etc.), fiberglass, or the like. The one or more materials used to manufacture the engineered portion 106 may be selected based on the ability of the materials to withstand mechanical or thermal stresses. For example, materials may be chosen that have similar thermal expansion coefficients to limit the mechanical stresses that occur as a result of thermal expansion in the substrate 104. Similarly, a particular design may be chosen that provides adequate mechanical or thermal strength to survive stresses that occur during the manufacture or operation of a semiconductor device. In this way, the substrate 104 may resist bowing or fracture during manufacturing or operation.

In some implementations, the engineered portion 106 may be a sintered material formed by heating or compressing powder (e.g., silicon dust or any other powdered material) to form a solid structure. In some cases, the engineered portion 106 may include layers of laminate or other materials compressed to form a solid structure. Some implementations may utilize oriented strand principles, where individual strands of material may be compressed and overlapped to form a solid structure. For example, strands of fiberglass may be arranged in an overlapping fashion to create a structurally robust substrate 104. Silicon dust or any other conductive or semiconductive dust may be sintered with the strands of fiberglass to create a conductive or semiconductive substrate 104. In some implementations, corrugations may be formed in the engineered portion 106 of the substrate 104 to improve the mechanical strength of the substrate 104. Alternatively, or additionally, the mechanical strength of the substrate 104 may be improved by forming planar trusses in the engineered portion 106.

To enable circuitry to be disposed at the substrate 104, a semiconductive portion 108 may be adhered to the engineered portion 106. The semiconductive portion 108 may be transplanted from a donor wafer or a semiconductive ingot. The semiconductive portion 108 may adhere to the engineered portion 106 using a dielectric material (e.g., silicon oxide, silicon nitride, silicon carbide, silicon carbon nitride, etc.). In some implementations, the semiconductive portion 108 may be adhered using one or more adhesives. The semiconductive portion 108 may be a thin layer of semiconductive material sufficient for disposing circuitry thereat. Thus, the engineered portion 106 may be substantially thicker (e.g., 50, 100, 150, 200, 300, 400 percent thicker) than the semiconductive portion 108. In total, the substrate 104 may be thick enough to withstand processing, for example, 500, 550, 600, 650, 700, 750, 800, 850, or 900 microns. The back side of the substrate 104 (e.g., opposite the circuitry) may later be thinned (e.g., to less than 50, 100, 150, 200, or 250 microns) to reduce the size of the substrate 104 to enable it to satisfy the spatial requirements for packaging.

Once the substrate 104 has been fabricated, including the engineered portion 106 and the semiconductor portion 108, dielectric material 110 may be disposed on the substrate 104. The dielectric material 110 may be selectively removed and deposited on to provide circuitry. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, lithography, or other suitable techniques. The substrate 104 can be a wafer-level substrate or a singulated, die-level substrate. If the substrate 104 is a wafer-level substrate, the substrate 104 may be diced to singulate the multiple dies implemented on the substrate 104.

FIG. 2 is a simplified schematic cross-sectional view of a semiconductor device assembly 200 in accordance with embodiments of the present technology. Similar to the semiconductor device assembly illustrated in FIG. 1, the semiconductor device assembly 200 can correspond to a single semiconductor die 202 or multiple semiconductor dies implemented on the substrate 204. The substrate 204 may include a first engineered portion 206, a second engineered portion 208, and a semiconductive portion 210. The first engineered portion 206 and the second engineered portion 208 may have different mechanical structures. In some implementations, the first engineered portion 206 may have a lesser mechanical strength than the second engineered portion 208. In some cases, the first engineered portion 206 may be optimized for material or manufacturing cost and manufacturing time, while the second engineered portion 208 may be optimized for mechanical or thermal strength.

The first engineered portion 206 may be substantially thicker (e.g., 50, 75, 100, 150, 200, 300 percent thicker) than the second engineered portion 208. The second engineered portion 208 may be disposed between the first engineered portion 206 and the semiconductive portion 210. In this way, when the back side of the substrate 204 is thinned prior to packaging, the thinning may be exclusive to the first engineered portion 206 and not the second engineered portion 208. The second engineered portion 208 may have a thickness that is less than or equal to the thickness of the substrate 204 after it has been thinned. Thus, the thinned substrate may include all of the second engineered portion 208. In other implementations, the second non-crystalline portion 208 may be thinned during substrate thinning, and the thinned substrate may include a portion of the second engineered portion 208. If the second engineered portion 208 is optimized to provide mechanical or thermal strength, the thinned substrate may include the strongest portion of the substrate 204, thereby improving the integrity of the die and enabling additional designs (e.g., higher die stacks) to be implemented.

Any number of designs may be implemented to form the first engineered portion 206 and the second engineered portion 208. For example, the first engineered portion 206 or the second engineered portion 208 can include a sintered material, layers of material (e.g., laminate) compressed into a solid structure, oriented strands of material compressed into a solid structure, a corrugated material, or material arranged to form one or more trusses. As a non-limiting example, the first engineered portion 206 could be a sintered material, compressed layers of material, or oriented strands of compressed material, and the second engineered portion 206 could include one or more corrugations or one or more planar trusses. The corrugations or trusses can be designed to provide mechanical strength in areas that are likely to experience high stresses. In some cases, the corrugations or trusses may prevent bowing or fracture of the substrate 204.

The second engineered portion 208 may adhere to the first engineered portion 206 using any appropriate method. For example, an adhesive or dielectric may directly attach the first engineered portion 206 and the second engineered portion 208. In some instances, the first engineered portion 206 and the second engineered portion 208 may be a single continuous structure without a seam separating them. The semiconductive portion 210 may adhere directly to the second engineered portion 208 using any appropriate method (e.g., adhesion, dielectric bonding, compressive bonding, or the like), and a layer of dielectric material 212 may be disposed at the semiconductive portion 210. Circuitry may be disposed at the layer of dielectric material 212 through deposition and removal of material to provide functionality to the semiconductor die 202.

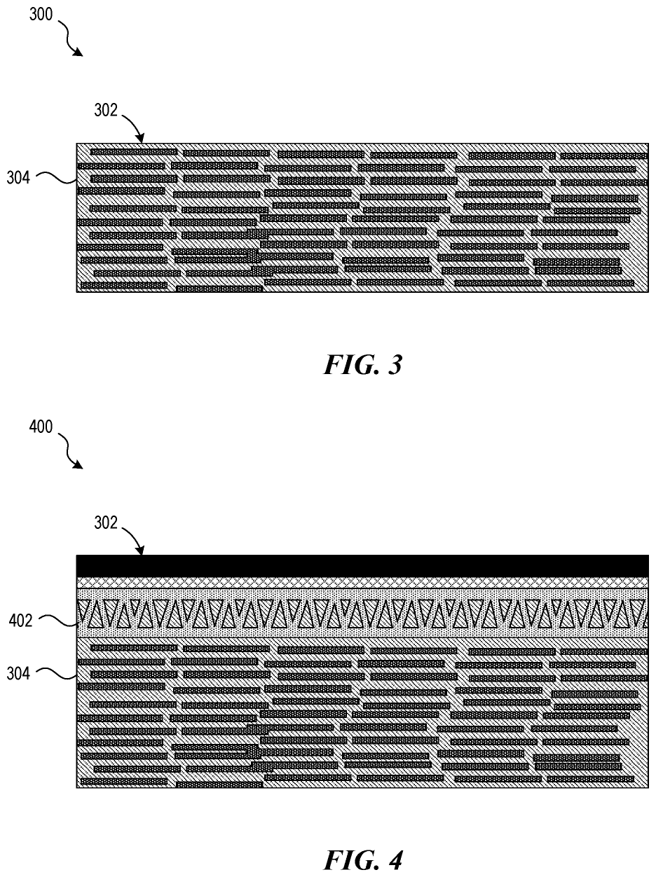

FIGS. 3-9 illustrate simplified schematic cross-sectional views of a series of steps for fabricating semiconductor device assemblies in accordance with an embodiment of the present technology. In some embodiments, the fabrication may be performed at the wafer-level, panel-level, strip-level, package-level, or die-level. Thus, in some embodiments, multiple semiconductor devices may be fabricated on a single substrate, and the multiple devices may be separated from one another during fabrication. In other embodiments, the substrates may be pre-singulated substrates, and a single semiconductor device may be fabricated on the substrate.

Beginning with FIG. 3 at stage 300, a substrate 302 is created. To create the substrate 302, a first engineered portion 304 may be created. The first engineered portion 304 may be mechanically engineered to provide a mechanically or thermally robust substrate 302. Any number of techniques may be used to create the first engineered portion 304. For example, the engineered material can include a sintered material, layers of material (e.g., laminate) compressed into a solid structure, oriented strands of material compressed into a solid structure, a corrugated material, or material arranged to form one or more trusses. In some implementations, the first engineered portion 304 may make up the entire engineered portion of the substrate 302. In other implementations, the substrate 302 may include a second engineered portion having a different structure from the first engineered portion 304, as illustrated in FIG. 4.

Turning to FIG. 4 at stage 400, a second engineered portion 402 of the substrate 302 is created. The second engineered portion 402 may be disposed on top of the first engineered portion 304. The first engineered portion 304 may make up a majority of the substrate 302. In some cases, the first engineered portion 304 may be made of a cost-efficient material or with a simpler design than a second engineered portion 402. For example, the first non-crystalline portion 304 could be a sintered material, compressed layers of material, or oriented strands of compressed material, and the second engineered portion 402 could include one or more corrugations or one or more planar trusses. The corrugations or trusses can be designed to provide mechanical strength in areas that are likely to experience high stresses. In this way, the second engineered portion 304 may have a higher mechanical strength (e.g., tensile strength, compressive strength, shear strength, etc.) than the first engineered portion 304. As a result, the second engineered portion 402 may be more capable of resisting deformation (e.g., bowing) or failure. In contrast to some SOIs, the first engineered portion 304 and the second engineered 402 portion may not include solid glass. Once the engineered portion has been created, a semiconductive portion may be transplanted onto the substrate 302.

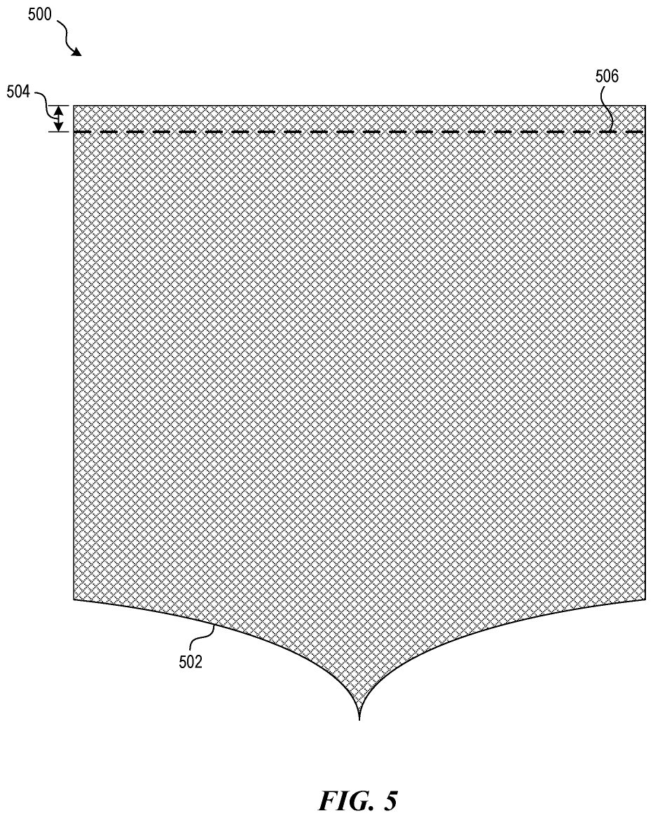

Turning next to FIG. 5 at stage 500, a portion of a semiconductive ingot 502 (e.g., silicon ingot) is implanted with ions to a depth 504 to enable semiconductive material to be transplanted from the semiconductive ingot 502 to the substrate. The semiconductive ingot 502 may correspond to the silicon structure that is sliced into wafers. In some implementations, a donor wafer may be used to transplant semiconductive material to the substrate. For example, a wafer may be sliced from a semiconductive ingot and used to transplant semiconductive material onto substrates. In these implementations, yield may be reduced due to the thickness of the cutting device (e.g., saw) used to slice the semiconductive ingot into wafers. Moreover, each transplant may reduce the thickness of the donor wafer until it no longer sufficient size to support another transplant. At this time, the donor wafer may be discarded or repurposed. In contrast to these implementations, some substrates described herein may receive semiconductive material from a semiconductive ingot 502 before it is sliced into wafers. In doing so, yield loss due to the thickness of the cut and discarding the donor wafer is reduced.

The semiconductive material may be transplanted to the substrate by ion cutting. For example, ions (e.g., hydrogen ions) may be implanted in the semiconductive ingot 502 to a depth 504. The depth 504 may correspond to the thickness of the semiconductive material on the substrate (e.g., the thickness of semiconductive material needed to dispose circuitry). In some cases, the depth 504 may be greater than the thickness of the semiconductive material on the substrate such that the semiconductive material may be planarized after it is transplanted. By implanting ions in the semiconductive ingot 502, the bonds in the semiconductive ingot 502 may be separated. As a result, the semiconductive ingot 502 may be weakened along a line 506 at which the ions are implanted.

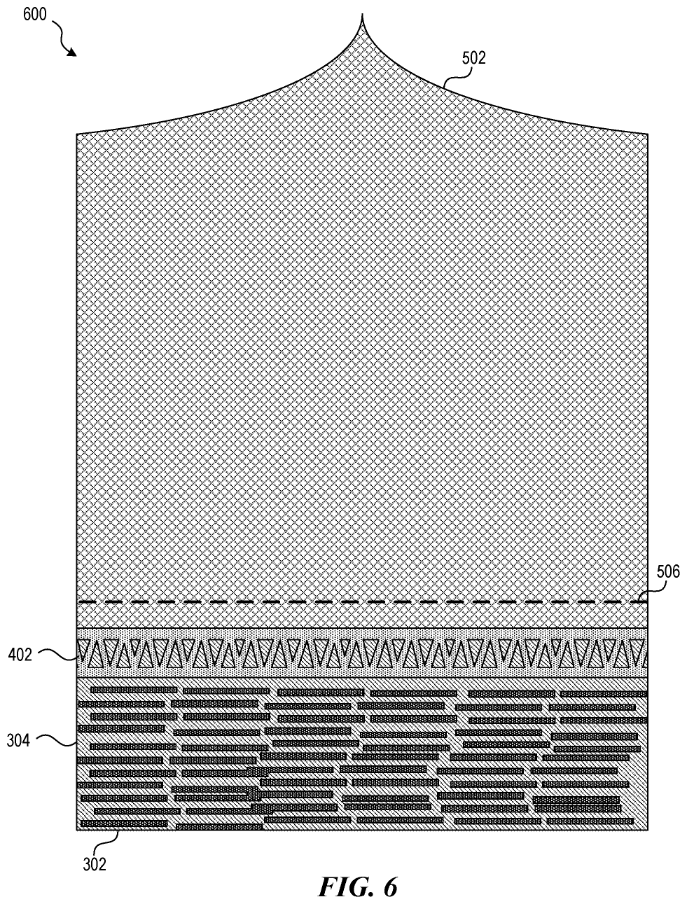

Turning next to FIG. 6 at stage 600, the semiconductive ingot 502 may be adhered to the substrate 302. The substrate 302 may be directly adhered to a same side at which the ions are implanted in the semiconductive ingot 502 (e.g., close to the line 506). If the engineered portion includes a first engineered portion 304 and a second engineered portion 402, the semiconductive ingot 502 may be adhered to the substrate 302 at the second engineered portion 402. The semiconductive ingot 502 may be adhered to the substrate 302 through any appropriate method, for example, by an adhesive or dielectric material.

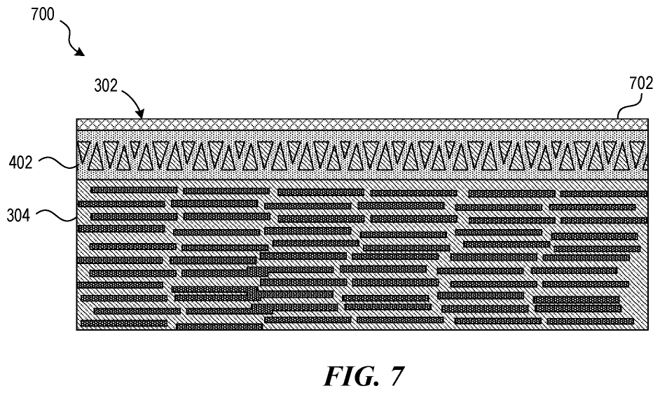

Turning next to FIG. 7 at stage 700, a portion of the semiconductive ingot is separated from the remaining semiconductive ingot to create a semiconductive portion 702 of the substrate 302. The semiconductive portion 702 may be separated from the semiconductive ingot at the line at which the ions are implanted. Separating the semiconductive ingot may include inducing stress in the semiconductive ingot at the line by providing lateral force to the semiconductive ingot or heating the semiconductive ingot. Given that the semiconductive ingot has been weakened along the line at which the ions are implanted, the semiconductive ingot may separate along this line. After separating, the semiconductive portion 702 may remain adhered to the substrate 302. In some implementations, the semiconductive portion 702 may be planarized to improve the planarity of the semiconductive surface.

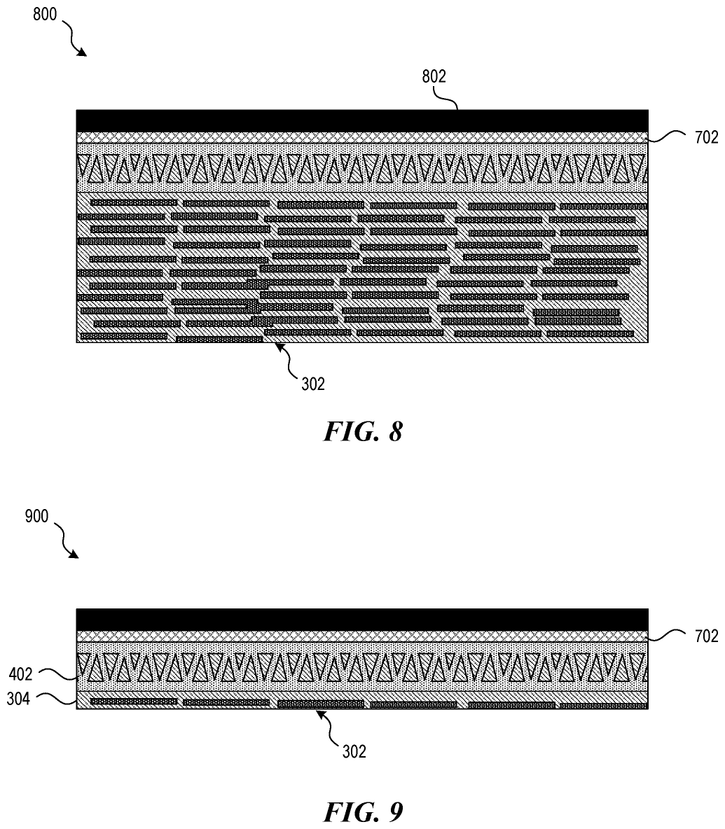

Turning next to FIG. 8 at stage 800, a layer of dielectric material 802 is deposited on the semiconductive portion 702 of the substrate 302. The layer of dielectric material 802 may be deposited through any appropriate technique, for example, using chemical vapor deposition, physical vapor deposition, atomic layer deposition, plating, electroless plating, spin coating, and/or other suitable techniques. The dielectric material 802 is then etched and material is deposited at the dielectric material 802 to implement circuitry and provide functionality to the semiconductor device.

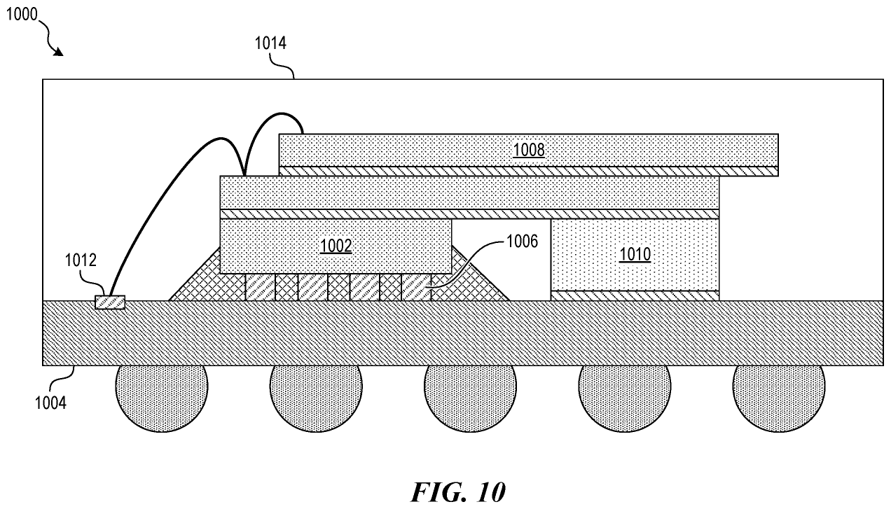

Turning next to FIG. 9 at stage 900, the substrate 302 is thinned at a back side of the substrate 302 (e.g., opposite the circuitry). In some implementations, the thinning may be exclusive to the first engineered portion 304. In this way, the second engineered portion 402 may not undergo the thinning. In some implementations, the substrate 302 may be thinned to between 100 and 200 microns. The resulting dies may then be packaged into a semiconductor device. If the substrate 302 is a wafer-level substrate that implements multiple semiconductor dies, the substrate 302 may be diced to singulate the dies. The singulated dies may then be packaged into one or more semiconductor devices, for example, as shown in FIG. 10.

FIG. 10 illustrates a simplified schematic semiconductor device assembly 1000 in accordance with an embodiment of the present technology. As can be seen with reference to FIG. 10 the semiconductor device assembly 1000 can include a logic die 1002 assembled onto a package-level substrate 1004 (e.g., in a flip-chip arrangement). Interconnects 1006 may be formed between the logic die 1002 and the substrate 1004. Memory dies 1008 can be mounted to the logic die 1002, a spacer 1010, or to other memory dies. The logic die 1002 or the memory dies 1008 may be implemented on an engineered substrate, as described herein. The memory dies 1008 may electrically couple through wires that connect the memory dies to bond pads 1012 on the substrate 1004. Similarly, the logic die 1002 and the memory dies 1008 may be electrically coupled through the substrate 1004 using the wires. Although not illustrated, the logic die 1002 or the memory dies 1008 may include through vias that extend through the substrate to enable the logic dies 1002 and the memory dies 1008 to transport electrical communications between one another or the package-level substrate 1004. As such, the semiconductor device assembly 1000 can be a vertical stack of semiconductor dies mounted to one another.

The substrate 1004 can further include package-level contact pads that provide external connectivity (e.g., via solder balls) to the logic die 1002 or the memory dies 1004 (e.g., power, ground, and I/O signals) through traces, lines, vias, and other electrical connection structures (not illustrated) in the substrate 1004 that electrically connect the package-level contact pads to contact pads at an upper surface of the substrate 1004. An underfill material (e.g., capillary underfill) can be provided between the logic die 1002 and the substrate 1004 to provide electrical insulation to the interconnects 1006 and structurally support the semiconductor dies. The assembly 1000 can further include an encapsulant material 1014 (e.g., mold resin compound or the like) that at least partially encapsulates the semiconductor dies and the substrate 1004 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, e.g., a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-10 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

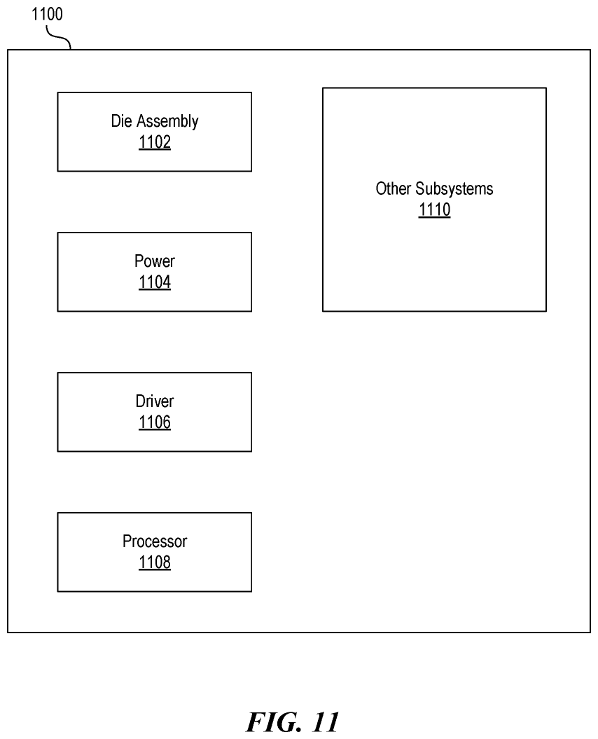

Any one of the semiconductor devices and semiconductor device assemblies described above with reference to FIGS. 1-10 can be incorporated into any of a myriad of larger and/or more complex systems, a representative example of which is system 1100 shown schematically in FIG. 11. The system 1100 can include a semiconductor device assembly 1102 (e.g., or a discrete semiconductor device), a power source 1104, a driver 1106, a processor 1108, and/or other subsystems or components 1110. The semiconductor device assembly 1102 can include features generally similar to those of the semiconductor device assemblies described above with reference to FIGS. 1-10. The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, vehicles, appliances and other products. Components of the system 1100 may be housed in a single unit or distributed over multiple, interconnected units (e.g., through a communications network). The components of the system 1100 can also include remote devices and any of a wide variety of computer readable media.

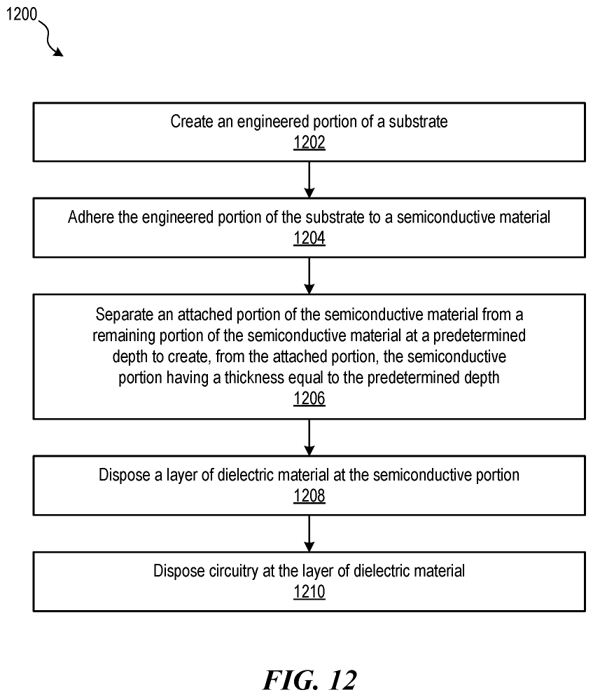

FIG. 12 illustrates an example method 1200 for fabricating a semiconductor device assembly in accordance with an embodiment of the present technology. The method 1200 may, for illustrative purposes, be described with respect to features, components, or elements of FIGS. 1-11. Although illustrated in a particular configuration, one or more operations of the method 1200 may be omitted, repeated, or reorganized. Additionally, the method 1200 may include other operations not illustrated in FIG. 12, for example, operations detailed in one or more other methods described herein.

At 1202, an engineered portion 106 of a substrate 302 may be created. In some implementations, creating the engineered portion 106 may include creating a first engineered portion 304 and a second engineered portion 402. The first engineered portion 304 may be a less costly portion, while the second engineered portion 402 may be a portion designed to provide increased mechanical strength to the substrate 302. In some aspects, the second engineered portion 402 may include one or more corrugations or trusses.

At 1204, the engineered portion 106 of the substrate 302 may be adhered to a semiconductive material 502. In some cases, the semiconductive material 502 may include an ingot of semiconductive material (e.g., silicon) that has not been sliced into wafers. The engineered portion 106 may be adhered to the semiconductive material 502 by an adhesive or a dielectric material. At 1206, an attached portion of the semiconductive material 502 may be separated from a remaining portion of the semiconductive material 502 at a predetermined depth 504 to create, from the attached portion, a semiconductive portion 702 having a thickness equal to the predetermined depth 504. In some instances, the semiconductive material 502 may be separated using ion cutting at a line 506.

At 1208, a layer of dielectric material 802 is disposed at the semiconductive portion 702 of the substrate 302. At 1210, circuitry is disposed at the layer of dielectric material 802. In some examples, the method 1200 may include thinning the engineered portion 106 of the substrate 302. If the substrate 302 includes a first engineered portion 304 and a second engineered portion 402, thinning the substrate 302 may include thinning the substrate 302 at the first engineered portion 304 and opposite the semiconductive portion 702 such that the second engineered portion 402 does not undergo the thinning. In general, the method 1200 may enable an engineered substrate to be implemented.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a semiconductor die comprising:
a substrate having:
an engineered portion including one or more of: a sintered material, a corrugated material, oriented strands of material compressed to form a solid structure, layers of material compressed to form a solid structure, and a material arranged to form one or more planar trusses; and
a semiconductive portion adhered directly to the engineered portion;
a layer of dielectric material disposed at the semiconductive portion; and
circuitry disposed at the layer of dielectric material.

2. The semiconductor device assembly of claim 1, wherein the engineered portion is thicker than the semiconductive portion.

3. The semiconductor device assembly of claim 1, wherein the engineered portion includes fiberglass strands compressed to form a solid structure.

4. The semiconductor device assembly of claim 1, wherein the engineered portion includes a silicon dust sintered into a solid structure.

5. The semiconductor device assembly of claim 1, wherein the engineered portion includes layers of laminates compressed into a solid structure.

6. The semiconductor device assembly of claim 1, wherein the semiconductive portion is adhered directly to the engineered portion by a dielectric material.

7. The semiconductor device assembly of claim 1, wherein the engineered portion includes:
a first portion; and
a second portion disposed between the first portion and the semiconductive portion, the second portion including one or more corrugations or at least some of the one or more planar trusses.

8. The semiconductor device assembly of claim 1, further comprising:
a package-level substrate; and
an additional semiconductor die,
wherein the additional semiconductor die is mounted to the semiconductor die, and
wherein the semiconductor die and the additional semiconductor die are electrically coupled to the package-level substrate.

9. The semiconductor device assembly of claim 1, wherein the engineered portion includes a non-crystalline material.

10. A method for fabricating a semiconductor device assembly, comprising:
creating an engineered portion of a substrate, the engineered portion including one or more of: a sintered material, a corrugated material, oriented strands of material compressed to form a solid structure, layers of material compressed to form a solid structure, and a material arranged to form one or more planar trusses;
adhering the engineered portion of the substrate to a semiconductive material;
separating an attached portion of the semiconductive material from a remaining portion of the semiconductive material at a predetermined depth to create, from the attached portion, a semiconductive portion of the substrate that is adhered to the engineered portion, the semiconductive portion having a thickness equal to the predetermined depth;
disposing a layer of dielectric material at the semiconductive portion; and
disposing circuitry at the layer of dielectric material.

11. The method of claim 10, wherein:
the semiconductive material is a silicon ingot that has not been sliced into wafers; and
separating the attached portion of the semiconductive material includes using ion cutting to separate the silicon ingot at the predetermined depth.

12. The method of claim 10, wherein creating the engineered portion of the substrate includes:
creating a first portion; and
creating a second portion disposed between the first portion and the semiconductive portion, the second portion having one or more corrugations or trusses.

13. The method of claim 12, further comprising:
thinning the engineered portion of the substrate at the first portion and opposite the semiconductive portion such that the second portion does not undergo the thinning.

14. The method of claim 10, wherein adhering the engineered portion to the semiconductive material includes forming a dielectric bond between the engineered portion and the semiconductive material.

15. A semiconductor device substrate, comprising:
a semiconductive portion; and
an engineered portion including:
a first portion that includes one or more of: sintered material, layers of material compressed to form a solid structure, and oriented strands of material compressed into a solid structure; and
a second portion disposed between the first portion and the semiconductive portion and directly adhered to the semiconductive portion, the second portion including one or more of: a corrugated material and a material arranged to form one or more planar trusses.

16. The semiconductor device substrate of claim 15, wherein the engineered portion is thicker than the semiconductive portion.

17. The semiconductor device substrate of claim 15, wherein the first portion is thicker than the second portion.

18. The semiconductor device substrate of claim 15, wherein the second portion has a greater mechanical strength than the first portion.

19. The semiconductor device substrate of claim 15, wherein the first portion includes layers of laminates compressed into a solid structure.

20. The semiconductor device substrate of claim 15, wherein the semiconductive portion is adhered directly to the second portion by a dielectric material.
